(19) United States
(12) Patent Application Publication
(10) Pub. No.: US 2020/0219655 A1
(43) Pub. Date: Jul. 9, 2020

(54) Capacitor Array with Staggered Layer Structure for Millimeter Wave Frequency Band

(71) Applicant: National Chung-Shan Institute of Science and Technology, Taoyuan City (TW)

(72) Inventors: Shao-Wei Peng, Hsinchu County (TW); Hung-Ting Chou, New Taipei City (TW); Chien-Te Yu, Taoyuan City (TW)

(21) Appl. No.: 16/239,500

(22) Filed: Jan. 3, 2019

(51) Int. Cl. H01G 4/30; H03H 7/00; H01G 4/38; H01L 49/02

(52) U.S. Cl. CPC H01G 4/304; H01L 28/40; H01G 4/385; H03H 7/004

(57) ABSTRACT

A capacitor array with staggered-layer structure includes a plurality of capacitor units. Each of the plurality of capacitor units comprises a plurality of odd layers formed with a first slot; a first via formed in the first slot; a plurality of first connecting portion configured to connect the first via and the plurality of odd layers; a plurality of even layers formed with a second slot; a second via formed in the second slot; a plurality of second connecting portion configured to connect the second via and the plurality of even layers; wherein one of the plurality of odd layers is adjacent to one of the plurality of even layers to form a staggered-layer structure.

### BACKGROUND OF THE INVENTION

### 1. Field of the Invention

The present invention relates to a capacitor array with staggered layer structure, and more particularly, to a capacitor array with staggered layer structure for millimeter wave frequency band.

### 2. Description of the Prior Art

Most conventional multi-layer capacitors are formed of ceramic dielectric materials or the like. Such multi-layer capacitors include a capacitor having a plurality of laminated dielectric layers, a plurality of pairs of mutually opposed first inner electrodes and a plurality of pairs of mutually opposed second inner electrodes alternately disposed in a direction in which the dielectric layers are laminated, the pairs of first inner electrodes and the second inner electrodes opposing via the dielectric layers so as to define a plurality of capacitor units.

In a high frequency circuit (e.g., millimeter wave frequency band from 5 GHz to 160 GHz) including a power supply line, which is used for a micro processing unit incorporating such a multi-layer capacitor, both the multi-layer capacitor and the micro processing unit must follow the design rule (e.g., metal density rule) for the same CMOS (Complementary Metal-Oxide-Semiconductor) process.

Therefore, how to design the capacitor unit and array with staggered layer structure for millimeter wave frequency band and adapted to the CMOS process has become a topic in the industry.

### SUMMARY OF THE INVENTION

It is therefore an objective of the present invention to provide a capacitor array with staggered layer structure for millimeter wave frequency band.

The present invention discloses a capacitor unit with staggered-layer structure, comprising a plurality of odd layers, wherein each of the plurality of odd layers is formed with a first slot, and not adjacent to another one of the plurality of odd layers; a first via formed in the first slot; a plurality of first connecting portion corresponding to the plurality of odd layers, formed in the first slot, and configured to connect the first via and the plurality of odd layers; a plurality of even layers, wherein each of the plurality of even layers is formed with a second slot, and not adjacent to another one of the plurality of even layers; a second via formed in the second slot; and a plurality of second connecting portion corresponding to the plurality of even layers, formed in the second slot, and configured to connect the second via and the plurality of even layers; wherein one of the plurality of odd layers is adjacent to one of the plurality of even layers to form a staggered-layer structure.

The capacitor unit with staggered-layer structure provides is applicable for CMOS process to be utilized as a power source trace as well as density cell to satisfy design rule for metal density. A plurality of the capacitor units may be coupled and arranged to be the capacitor array adapted to at least one of alignment, non-alignment, overlapping and non-overlapping designs. Moreover, the capacitor array with staggered-layer structure provides characteristics of wide bandwidth, smooth and low impedance, and low conduction loss for bypass capacitor design, which is suitable for power source trance for millimeter wave frequency band.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates an isotropic view of a capacitor unit according to an embodiment of the present invention.

FIG. 2A illustrates a top view of the capacitor unit in FIG. 1.

FIG. 2B illustrates a sectional view of the capacitor unit 10 in FIG. 1.

FIG. 3A is a top view of an odd layer of the capacitor unit 10 in FIG. 1.

FIG. 3B is a top view of an even layer of the capacitor unit 10 in FIG. 1.

FIG. 4A is a sectional view of odd layers of the capacitor unit 10 in FIG. 1.

FIG. 4B is a sectional view of even layers of the capacitor unit 10 in FIG. 1.

FIG. 5 illustrates a top view of a 2*2 capacitor array according to an embodiment of the present invention.

FIG. 6 illustrates a top view of a 2*2 capacitor array according to an embodiment of the present invention.

FIG. 7 illustrates a top view of a 2*2 capacitor array according to an embodiment of the present invention.

FIG. 8 illustrates a top view of a 2*2 capacitor array according to an embodiment of the present invention.

FIG. 9A is an isotropic view of a capacitor array according to an embodiment of the present invention.

FIG. 9B is a simulated impedance to frequency diagram of the capacitor array.

FIG. 9C is a simulated capacitance to frequency diagram of the capacitor array.

FIG. 10A is an isotropic view of a distributed bypass capacitor array according to an embodiment of the present invention.

FIG. 10B is a transmitter comprising an equivalent circuit of the distributed bypass capacitor array in FIG. 10A.

FIG. 11A is an isotropic view of a lumped bypass capacitor array according to an embodiment of the present invention.

FIG. 11B is a transmitter comprising an equivalent circuit of the lumped bypass capacitor array in FIG. 11A.

FIG. 12A is a simulated impedance to frequency diagram of the distributed bypass capacitor array and the lumped bypass capacitor array.

FIG. 12B is a simulated isolation to frequency diagram of the distributed bypass capacitor array and the lumped bypass capacitor array.

FIG. 13 illustrates a conduction loss of a CMOS process transmitting circuit and corresponding equivalent circuit.

FIG. 14A illustrates an equivalent circuit of a capacitor for parallel-plates model.

FIG. 14B illustrates an equivalent circuit of a capacitor unit with staggered-layer structure.

### DETAILED DESCRIPTION

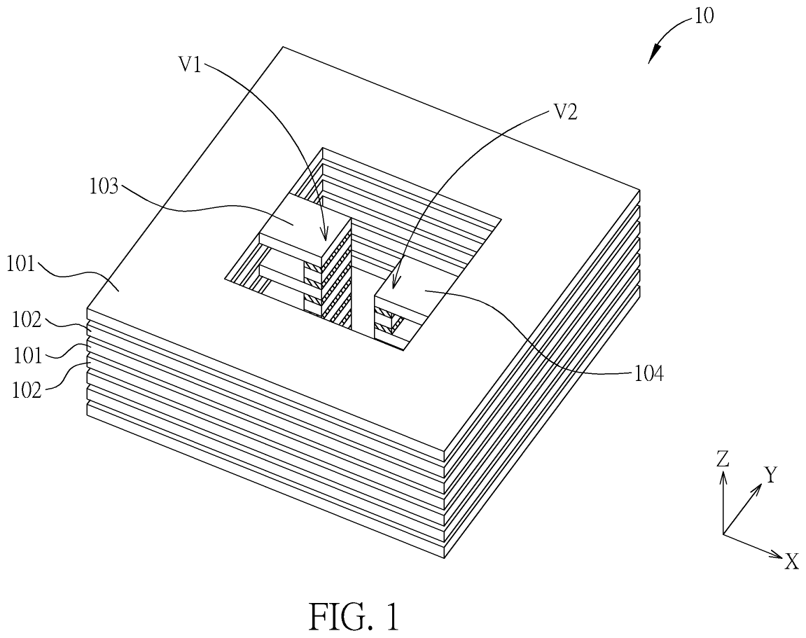

FIG. 1 illustrates an isotropic view of a capacitor unit 10 according to an embodiment of the present invention. The capacitor unit 10 includes odd layers 101, even layers 102, vias V1 and V2, and connecting portions 103 and 104. The capacitor unit 10 may be utilized in a transmitter operating in millimeter wave frequency band, e.g. 5-160 GHz frequency band. The odd layers 101, the even layers 102, the vias V1 and V2, and the connecting portions 103 and 104 are made of metal.

As shown in FIG. 1, the capacitor unit 10 is formed with a staggered structure comprising the odd layers 101 and the even layers 102 with rectangular topology. A sub capacitor may be formed by coupling one of the odd layers 101 with neighboring one of the even layers 102.

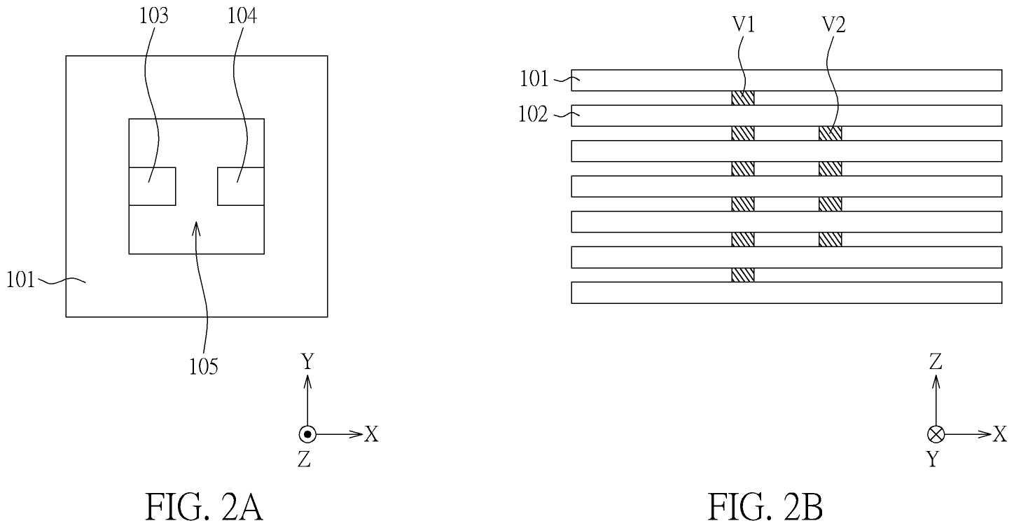

FIG. 2A illustrates a top view of the capacitor unit 10 in FIG. 1. The odd layers 101 and the even layers 102 with rectangular topology are formed with slots 105 to obey design rules for capacitor array structure, e.g., a total width of the capacitor array structure may not be too wide or a total metal density of the capacitor array structure may not be too high.

FIG. 2B illustrates a sectional view of the capacitor unit 10 in FIG. 1. The vias V1 and V2 and the connecting portions 103 and 104 are formed inside the slots 105. The connecting portions 103 are configured to connect the via V1 and the odd layers 101, and the connecting portions 104 are configured to connect the via V2 and the even layers 102.

In such a structure, there is a high flexibility of connections between the capacitor unit 10 and other metal elements. For example, the capacitor unit 10 may connect to other metal elements through any sides of the rectangular topology, and any one of the odd layers 101, any one of the even layers 102.

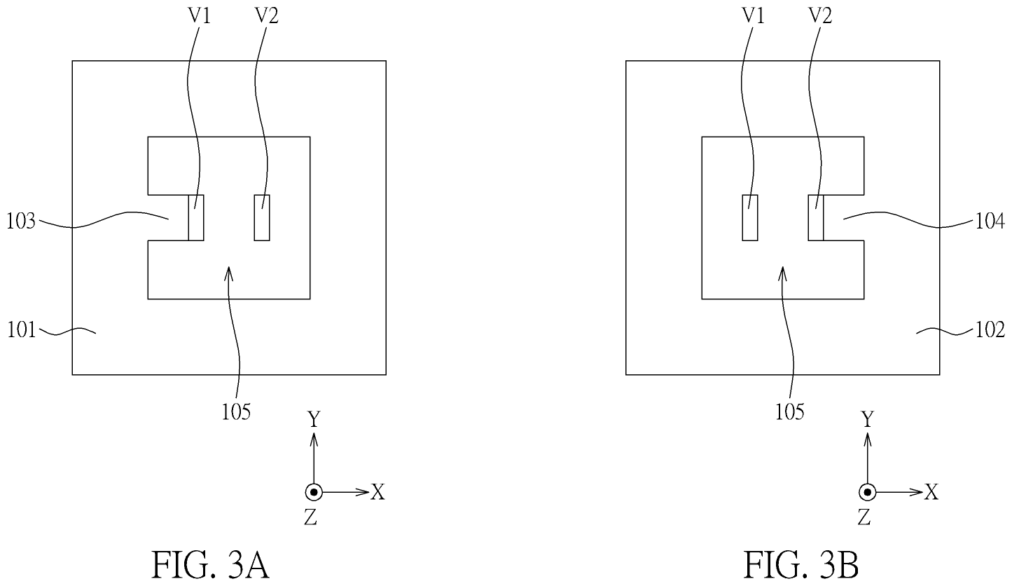

FIG. 3A is a top view of an odd layer of the capacitor unit 10 in FIG. 1, wherein the via V1 is configured to connect the odd layers 101 through the connecting portions 103. FIG. 3B is a top view of an even layer of the capacitor unit 10 in FIG. 1, wherein the via V2 is configured to connect the even layers 102 through the connecting portions 104.

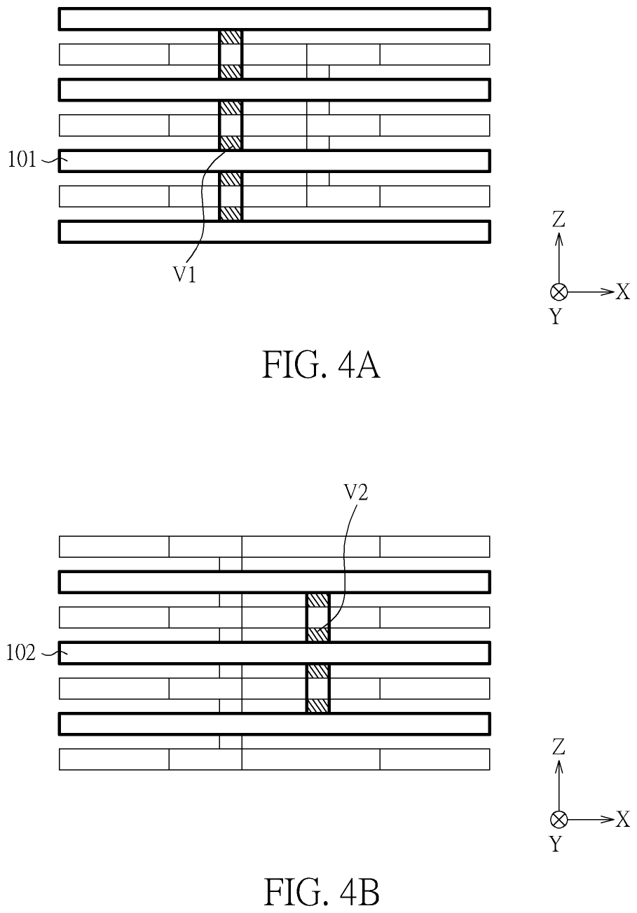

FIG. 4A is a sectional view of odd layers of the capacitor unit in FIG. 1, wherein the via V1 is configured to connect the first, third, fifth and seventh layers to ensure they have a same electric potential. FIG. 4B is a sectional view of even layers of the capacitor unit in FIG. 1, wherein the via V2 is configured to connect the second, fourth and sixth layers to ensure they have a same electric potential. In this embodiment, there are seven layers in total in the capacitor unit 10, which is not limited. In the present invention, the staggered structure of the capacitor array is applicable for at least four layers. In other words, a first number of the plurality of odd layers and a second number of the plurality of even layers are integers greater than 1.

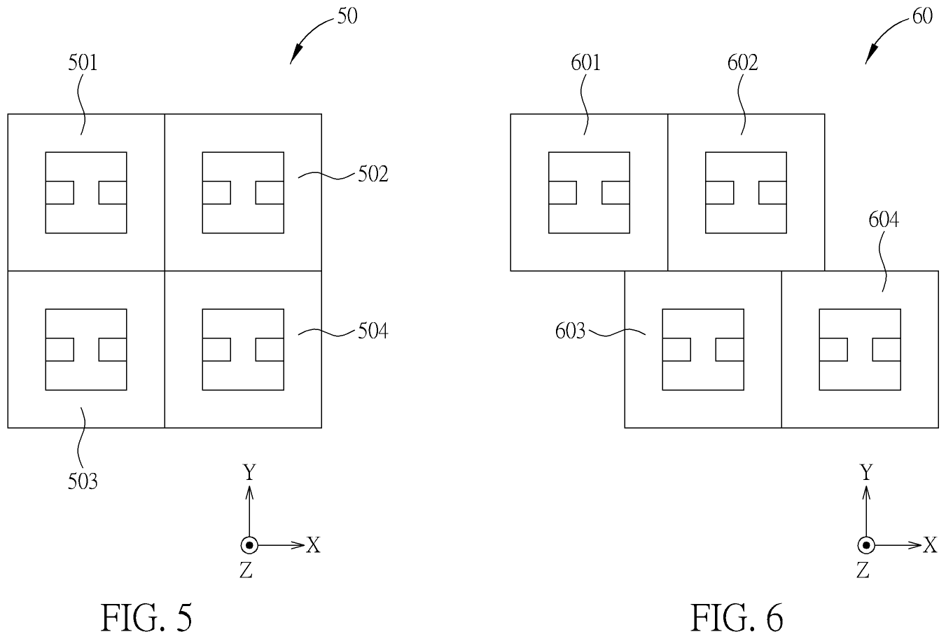

A plurality of the capacitor units 10 may be arranged and coupled together to form a capacitor array of an m*n matrix, wherein m and n are integers greater than zero. For example, FIG. 5 illustrates a top view of a 2*2 capacitor array 50 according to an embodiment of the present invention.

The capacitor array 50 includes four capacitor units 501, 502, 503 and 504. The capacitor unit 501 is formed adjacent to the capacitor units 502 and 503, and not adjacent to the capacitor unit 504. Two horizontal edges of the capacitor unit 501 along a first direction (e.g., X direction) are aligned with two horizontal edges of the capacitor unit 502, and two vertical edges of the capacitor unit 501 along a second direction (e.g., Y direction) are aligned with two vertical edges of the capacitor unit 503. Projections of the capacitor units 501, 502, 503 and 504 onto a plane formed by the first direction and the second direction (e.g., XY plane) are not overlapped.

FIG. 6 illustrates a top view of a 2*2 capacitor array 60 according to an embodiment of the present invention. The capacitor array 60 includes four capacitor units 601, 602, 603 and 604. The capacitor unit 601 is formed adjacent to the capacitor units 602 and 603, and not adjacent to the capacitor unit 604. Two horizontal edges of the capacitor unit 601 along a first direction (e.g., X direction) are aligned with two horizontal edges of the capacitor unit 602 and one horizontal edge of the capacitor units 603 and 604, and two vertical edges of the capacitor unit 601 along a second direction (e.g., Y direction) are not aligned with any vertical edges edge of the capacitor units 603 and 604. Projections of the capacitor units 601, 602, 603 and 604 onto the XY plane are not overlapped.

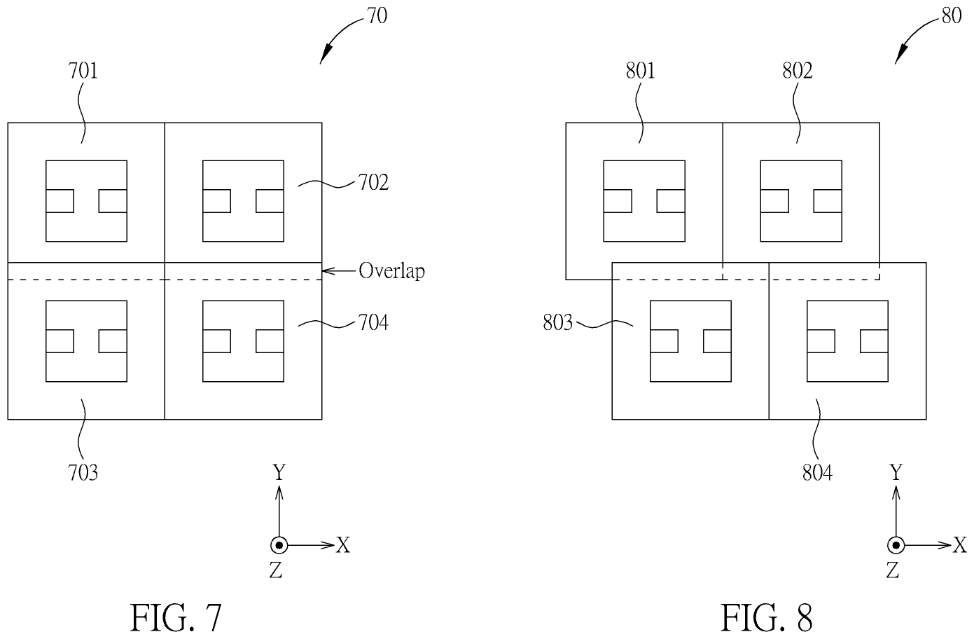

FIG. 7 illustrates a top view of a 2*2 capacitor array 70 according to an embodiment of the present invention. The capacitor array 70 includes four capacitor units 701, 702, 703 and 704. The capacitor unit 701 is formed adjacent to the capacitor unit 702. Two horizontal edges of the capacitor unit 701 along a first direction (e.g., X direction) are aligned with two horizontal edges of the capacitor unit 702, and two vertical edges of the capacitor unit 701 along a second direction (e.g., Y direction) are aligned with two vertical edges of the capacitor unit 703. A prof ection of the capacitor unit 701 onto the XY plane is overlapped with a projection of the capacitor unit 703, and the projection of the capacitor unit 701 is not overlapped with projections of the capacitor units 702 and 704 onto the XY plane.

FIG. 8 illustrates a top view of a 2*2 capacitor array 80 according to an embodiment of the present invention. The capacitor array 80 includes four capacitor units 801, 802, 803 and 804. The capacitor unit 801 is formed adjacent to the capacitor units 802. Two horizontal edges of the capacitor unit 801 along a first direction (e.g., X direction) is aligned with two horizontal edges of the capacitor unit 802, and vertical edges of the capacitor unit 801 along a second direction (e.g., Y direction) is not aligned with any vertical edge of the capacitor unit 803. A projection of the capacitor units 801 onto the XY plane is overlapped with a projection of the capacitor unit 803, and the projection of the capacitor unit 801 is not overlapped with projections of the capacitor units 802 and 804 onto the XY plane.

Note that sizes of the capacitor units may be determined according to design rules (e.g., metal width, spacing, and density rules) for CMOS (Complementary Metal-Oxide-Semiconductor) process. For example, the width of traces of the odd and even layers and connecting portions may be determined according to the metal width rule, and the area of the slot formed in the odd and even layers may be determined according to the metal spacing and density rules for CMOS process.

The capacitance C of a parallel-plates model is denoted as a function of

$$C = ∈ \cdot \frac{A}{d} ,$$

wnerein A is an area of two of the parallel-plates, d is a distance between the two parallel-plates, and E is a permittivity of a dielectric between the two parallel-plates.

The impedance Z of the capacitance C is denoted as a function of

$$Z = \frac{1}{ω \cdot C} \cdot ( \frac{Q + 1}{Q} ) ,$$

wherein ω is angular frequency, Q is quality factor. Accordingly, under a same distance and a varying frequency, an impedance of a distributed bypass capacitor varies smoother than an impedance of a lumped bypass capacitor.

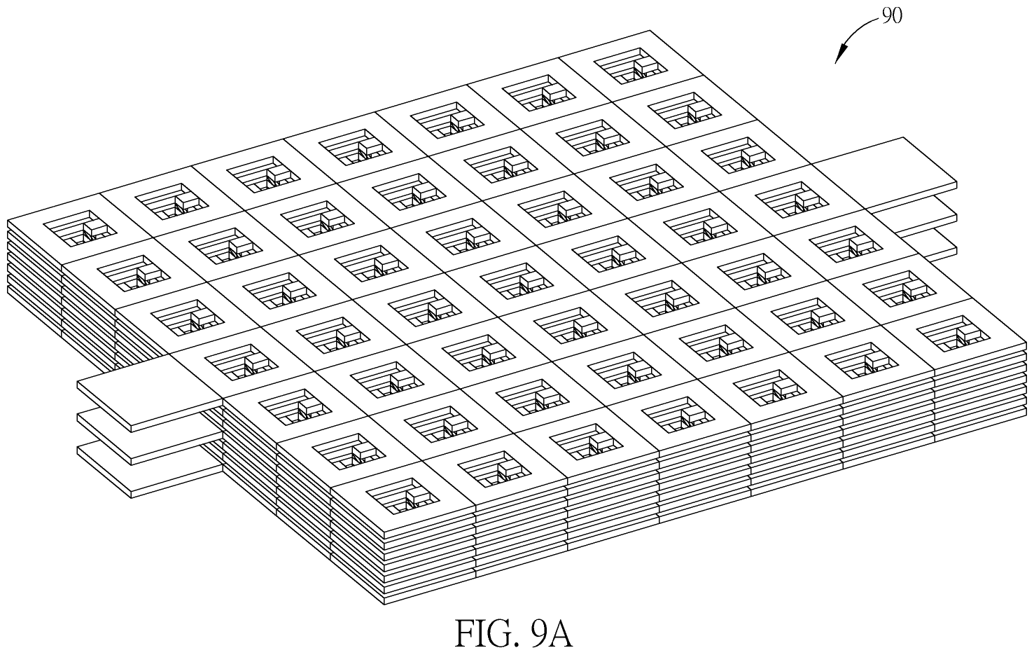

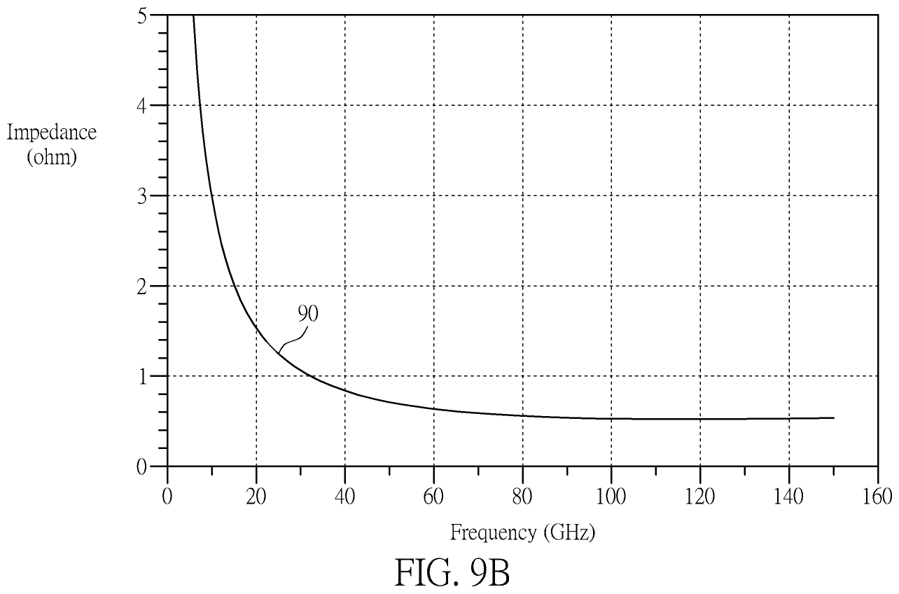

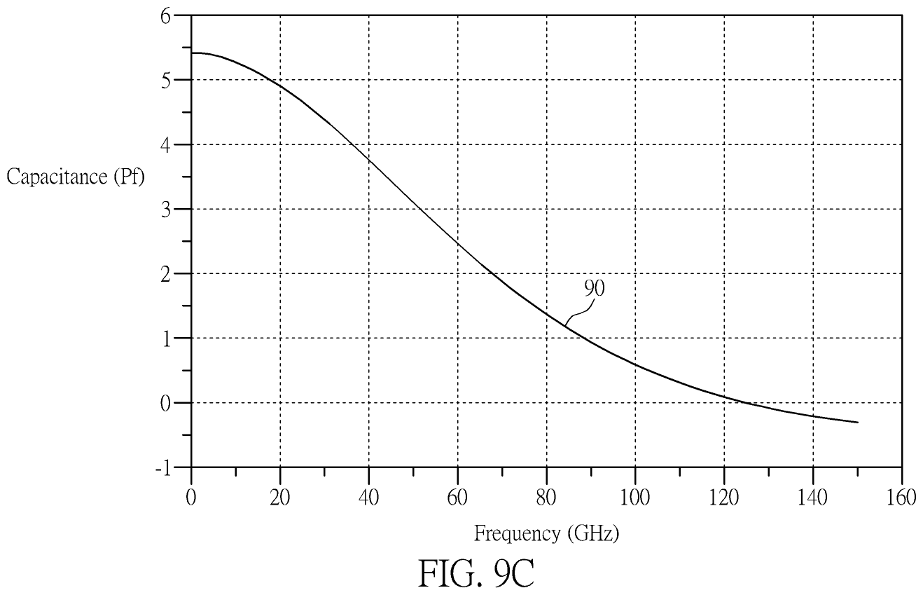

Specifically, FIG. 9A is an isotropic view of a capacitor array 90 according to an embodiment of the present invention. The capacitor array 90 includes 7*7 capacitor units with an area of 56*56 um². FIG. 9B is a simulated impedance to frequency diagram of the capacitor array 90. As observed from FIG. 9B, the capacitor array 90 has a characteristics of wide bandwidth and low (and smooth) impedance for bypass capacitor design. FIG. 9C is a simulated capacitance to frequency diagram of the capacitor array 90. As observed from FIG. 9C, the simulated capacitance for 100 MHz is 5.4 pF.

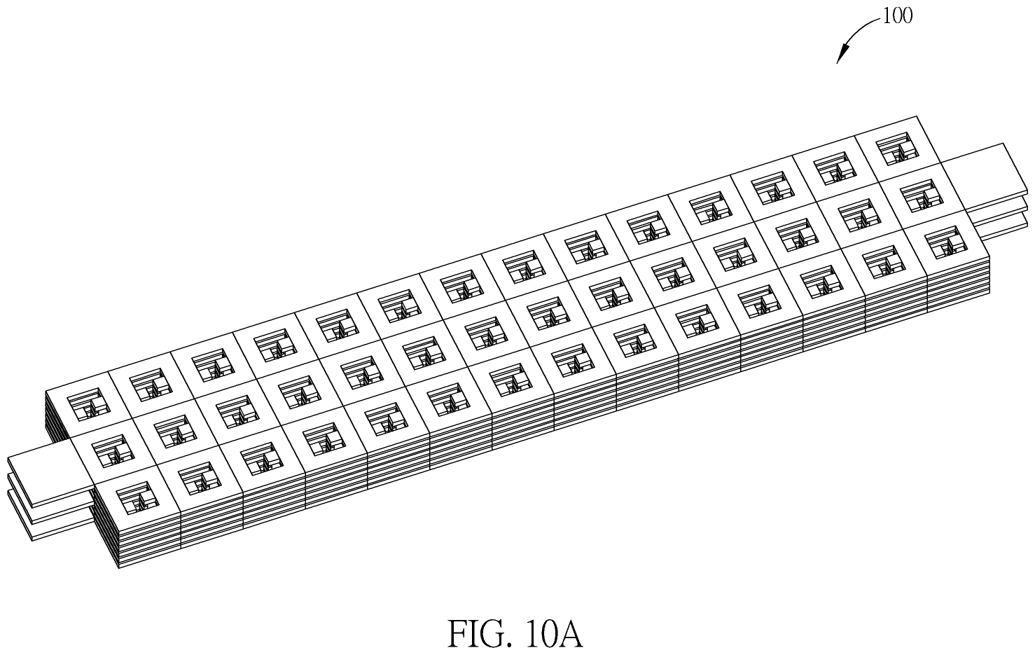

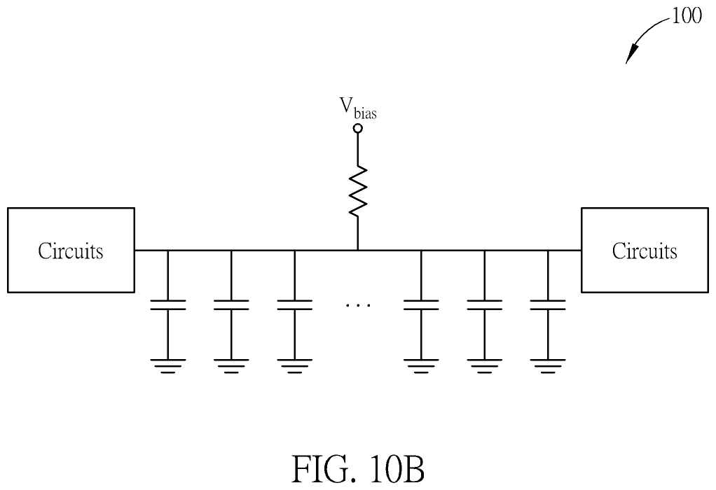

FIG. 10A is an isotropic view of a distributed bypass capacitor array 100 according to an embodiment of the present invention. The capacitor array 100 includes 14*3=42 capacitor units. FIG. 10B is a transmitter comprising an equivalent circuit of the distributed bypass capacitor array 100 in FIG. 10A. As observed from FIG. 10B, a capacitor sub-array including)*3 capacitor units may be represented by a sub-capacitor, and there are 14 sub-capacitors connected in parallel between two circuits. In this embodiment, one end of the capacitor sub-array is coupled to a power source V_{bias} and between two circuits (or radio-frequency signals), and another end of the capacitor sub-array is coupled to a ground. A distance between the two circuits is 112 um (micro meters).

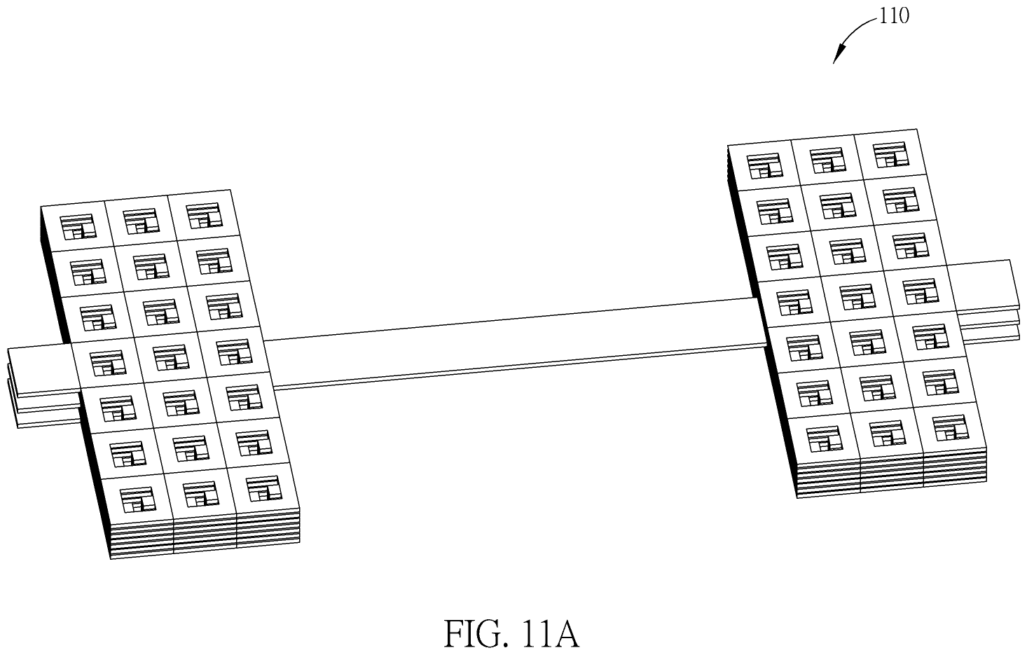

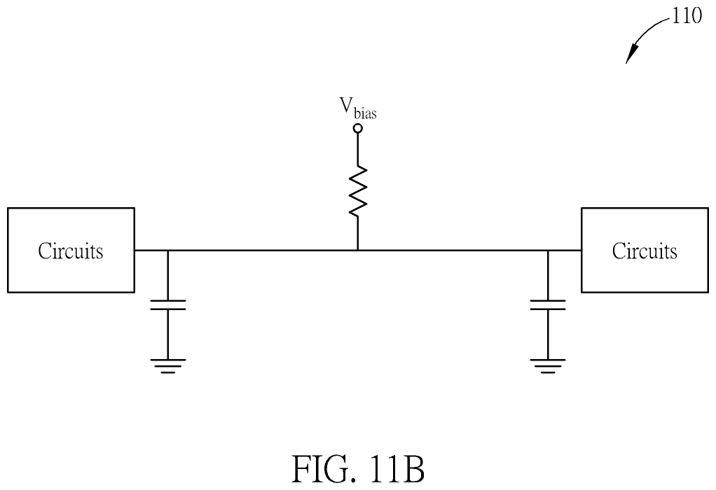

FIG. 11A is an isotropic view of a lumped bypass capacitor array 110 according to an embodiment of the present invention. The capacitor array 110 includes 3*7*2=42 capacitor units, and there are two capacitor sub-array including 3*7=21 capacitor units and a transmission line with 50 ohm for connecting the 2 sub-capacitors with 21 capacitor units. FIG. 11B is a transmitter comprising an equivalent circuit of the lumped bypass capacitor array 110 in FIG. 11A. As observed from FIG. 11B, one capacitor sub-array including 3*7=21 capacitor units may be represented by a sub-capacitor, and there are 2 sub-capacitors connected in parallel between two circuits. In this embodiment, one end of the capacitor sub-array is coupled to a power source V_{bias} and between two circuits (or radio-frequency signals), and another end of the capacitor sub-array is coupled to a ground. A distance between the two circuits is 112 um (micro meters).

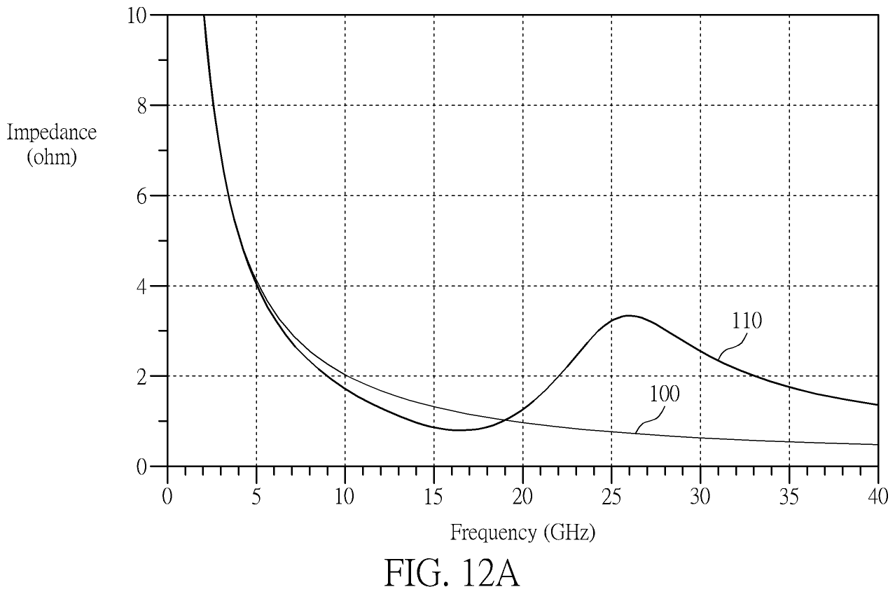

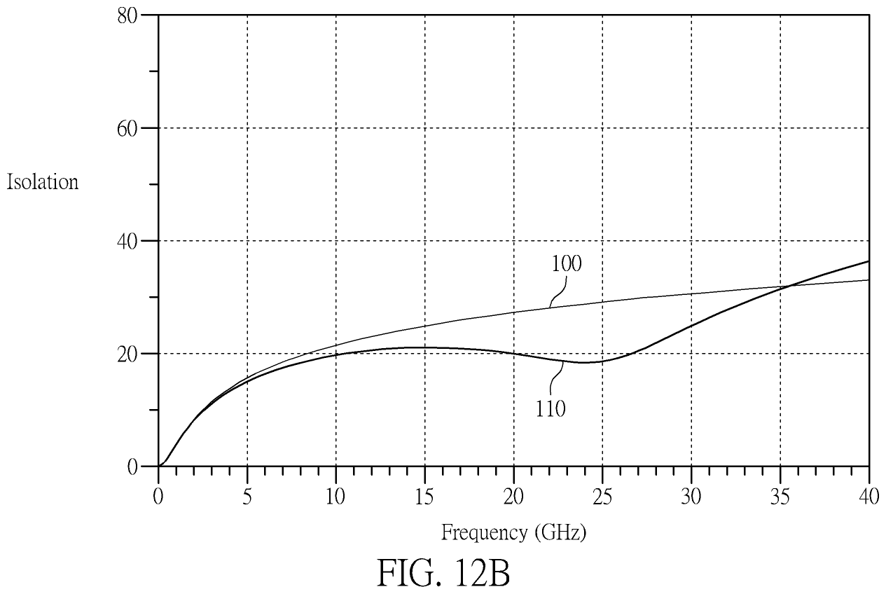

FIG. 12A is a simulated impedance to frequency diagram of the distributed bypass capacitor array 100 and the lumped bypass capacitor array 110. FIG. 12B is a simulated isolation to frequency diagram of the distributed bypass capacitor array 100 and the lumped bypass capacitor array 110. In FIGS. 12A and 12B, the impedance and isolation curves for the distributed bypass capacitor array 100 are denoted with a thin line, and the impedance and isolation curves for the lumped bypass capacitor array 110 are denoted with a thick line.

Note that both of the distributed bypass capacitor array 100 and the lumped bypass capacitor array 110 includes 42 capacitor units in total, and the distance of them are 112 um. As observed from FIG. 12A, the impedance of the lumped bypass capacitor array 110 rises at 26 GHz due to transmission line resonation. While the impedance of the distributed bypass capacitor array 100 is smooth without additional resonation, which provides more stable characteristics for bypass capacitor design. As observed from FIG. 12B, the isolation of the lumped bypass capacitor array 110 decreases at 24 GHz due to transmission line resonation. While the isolation of the distributed bypass capacitor array 100 is smooth without additional resonation, which provides more stable characteristics for bypass capacitor design.

In summary of the embodiment of FIG. 1 to FIG. 12,

(i) when using CMOS process, the capacitor unit may be utilized as a power source trace as well as density cell to satisfy design rule for metal density;

(ii) a plurality of the capacitor units may be coupled and arranged to be the capacitor array 50 as shown in FIG. 5 for alignment and non-overlapping design;

(iii) a plurality of the capacitor units may be coupled and arranged to be the capacitor arrays 60, 70, and 80 as shown in FIG. 6 to FIG. 8 for non-alignment and overlapping design;

(iv) the capacitor unit may be utilized for power source trance for millimeter wave band, wherein the odd (or even) layers are coupled to a ground, the remaining (even or odd) layers are coupled to the power source (and the circuits), and the capacitor unit operates as the bypass capacitor to have impedance with the characteristics of wide bandwidth and low impedance to provide smooth and stable bypass capacitor design;

(v) the transmission line of the lumped bypass capacitor array produces conduction loss and resonation to cause voltage drop (or IR drop for V=IR), and the distributed bypass capacitor array may solve the voltage drop due to the conduction loss and resonation.

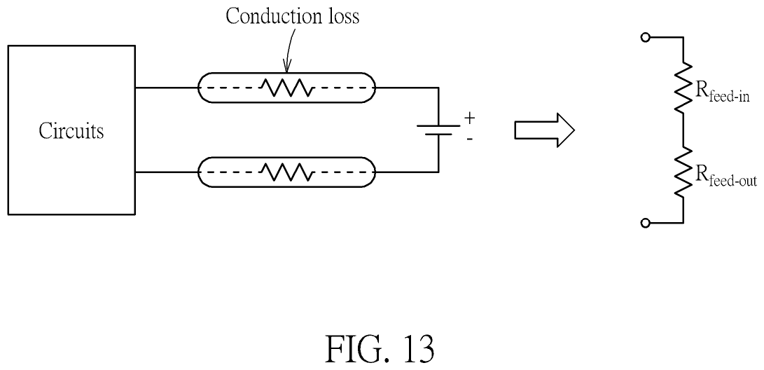

FIG. 13 illustrates a conduction loss of a CMOS process transmitting circuit and corresponding equivalent circuit. For thin metal CMOS process, the conduction loss should take considerations of power source feed-in line and return current route. Therefore, the equivalent circuit for conduction loss includes a feed-in resistance R_{feed-in} for the power source feed-in line and a feed-out resistance R_{feed-out} for the return current route.

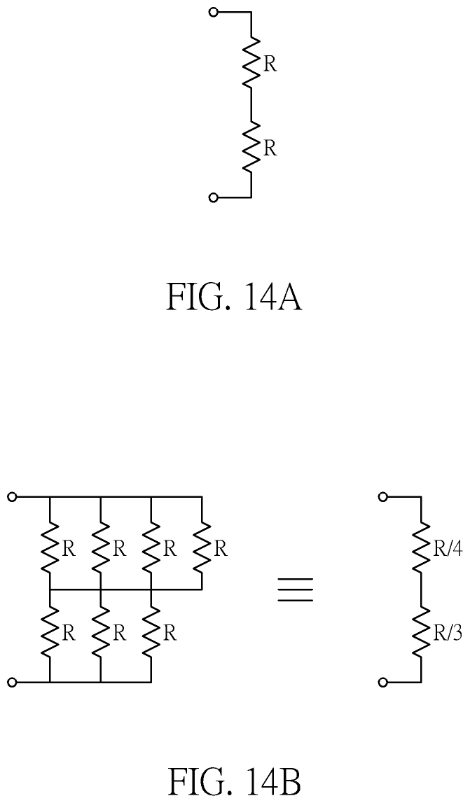

FIG. 14A illustrates an equivalent circuit of a capacitor for parallel-plates model. Consider the conduction loss, given that a feed-in resistance R is equal to a feed-out resistance R, so a total resistance is 2*R.

FIG. 14B illustrates an equivalent circuit of a capacitor unit with staggered-layer structure. Consider the conduction loss, given that a feed-in resistance is equivalent to four paralleled feed-in resistance R/4 (e.g., there are four odd layers in the capacitor unit), a feed-out resistance is equivalent to three paralleled feed-in resistance R/3 (e.g., there are three even layers in the capacitor unit), so a total resistance is R/4+R/3=7/12*R.

As observe from FIG. 14A and FIG. 14B, the total resistance of the capacitor unit of the present invention is smaller than the total resistance of the capacitor for parallel-plates model, i.e., 7/12*R is smaller than 2*R, to improve voltage drop (IR drop) due to conduction loss.

To sum up, the capacitor array with staggered-layer structure provides is applicable for CMOS process to be utilized as a power source trace as well as density cell to satisfy design rule for metal density. A plurality of the capacitor units may be coupled and arranged to be the capacitor array adapted to at least one of alignment, non-alignment, overlapping and non-overlapping designs. Moreover, the capacitor array with staggered-layer structure provides characteristics of wide bandwidth, smooth and low impedance, and low conduction loss for bypass capacitor design, which is suitable for power source trace for millimeter wave frequency band.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A capacitor unit with staggered-layer structure, for a capacitor array, comprising:
a plurality of odd layers, wherein each of the plurality of odd layers is formed with a first slot, and not adjacent to another one of the plurality of odd layers;
a first via formed in the first slot;
a plurality of first connecting portion corresponding to the plurality of odd layers, formed in the first slot, and configured to connect the first via and the plurality of odd layers;
a plurality of even layers, wherein each of the plurality of even layers is formed with a second slot, and not adjacent to another one of the plurality of even layers;
a second via formed in the second slot; and
a plurality of second connecting portion corresponding to the plurality of even layers, formed in the second slot, and configured to connect the second via and the plurality of even layers;
wherein one of the plurality of odd layers is adjacent to one of the plurality of even layers to form a staggered-layer structure.

2. The capacitor unit of claim 1, wherein the plurality of odd layers, the first slot, the plurality of even layers, the second slot are formed with a rectangular topology.

3. The capacitor unit of claim 1, wherein a first number of the plurality of odd layers and a second number of the plurality of even layers are integers greater than 1.

4. The capacitor unit of claim 1, wherein the plurality of capacitor units is arranged and coupled together to form the capacitor array of an m*n matrix, wherein m and n are integers greater than zero.

5. The capacitor unit of claim 1, wherein the capacitor array comprises:
a first capacitor unit;
a second capacitor unit coupled and adjacent to the first capacitor unit;
a third capacitor unit coupled and adjacent to the first capacitor unit; and
a fourth capacitor unit coupled and adjacent to the second and third capacitor units, and not adjacent to the first capacitor unit;
wherein horizontal edges of the first capacitor unit along a first direction is aligned with horizontal edges of the second capacitor unit, and vertical edges of the first capacitor unit along a second direction is aligned with vertical edges of the third capacitor unit;
wherein projections of the first, second, third and fourth capacitor units onto a plane formed by the first and second directions are not overlapped.

6. The capacitor unit of claim 1, wherein the capacitor array comprises:
a first capacitor unit;
a second capacitor unit coupled and adjacent to the first capacitor unit;
a third capacitor unit coupled and adjacent to the first capacitor unit; and
a fourth capacitor unit coupled and adjacent to the second and third capacitor units, and not adjacent to the first capacitor unit;
wherein two horizontal edges of the first capacitor unit along a first direction are aligned with two horizontal edges of the second capacitor unit, one horizontal edge of the third capacitor unit, and one horizontal edge of the fourth capacitor unit;
wherein two vertical edges of the first capacitor unit along a second direction are not aligned with any vertical edge of the third and fourth capacitor units;
wherein projections of the first, second, third and fourth capacitor units onto a plane formed by the first and second directions are not overlapped.

7. The capacitor unit of claim 1, wherein the capacitor array comprises:
a first capacitor unit;
a second capacitor unit coupled and adjacent to the first capacitor unit;
a third capacitor unit; and
a fourth capacitor unit coupled and adjacent to the third capacitor unit;
wherein two horizontal edges of the first capacitor unit along a first direction are aligned with two horizontal edges of the second capacitor unit, and two vertical edges of the first capacitor unit along a second direction are aligned with two vertical edges of the third capacitor unit;
wherein a projection of the first capacitor unit onto a plane formed by the first and second directions is overlapped with a projection of the third capacitor unit, and the projection of the first capacitor unit is not overlapped with projections of the second and fourth capacitor units onto the plane.

8. The capacitor unit of claim 1, wherein the capacitor array comprises:
a first capacitor unit;
a second capacitor unit coupled and adjacent to the first capacitor unit;
a third capacitor unit; and
a fourth capacitor unit coupled and adjacent to the third capacitor unit;
wherein two horizontal edges of the first capacitor unit along a first direction are aligned with two horizontal edges of the second capacitor unit;
wherein two vertical edges of the first capacitor unit along a second direction are not aligned with any vertical edge of the third capacitor unit;
wherein a projection of the first capacitor units onto a plane formed by the first and second directions is overlapped with a projection of the third capacitor unit, and the projection of the first capacitor unit is not overlapped with projections of the second and fourth capacitor units onto the plane.

9. The capacitor unit of claim 1, wherein the plurality of odd layers are connected to a power source and a radio-frequency signal, and the plurality of even layers are connected to a ground.
